(19) United States
(12) Patent Application Publication
(10) Pub. No.: US 2011/0316016 A1
(43) Pub. Date: Dec. 29, 2011

(54) LED CHIP PACKAGE STRUCTURE

(76) Inventor: Chi Chih LIN, Pingjhen City (TW)

(21) Appl. No.: 13/111,464

(22) Filed: May 19, 2011

(30) Foreign Application Priority Data
Jun. 25, 2010 (TW) 99120812

(51) Int. Cl. H01L 33/38

(52) U.S. Cl. 257/91; 257/E33.065

(57) ABSTRACT

An LED chip package structure includes a substrate; a first circuit pattern disposed on a surface of the substrate, wherein the first circuit pattern is divided into an electrical connection portion and a carrier portion; a second circuit pattern disposed on another surface of the substrate; a plurality of vias disposed in the substrate and connecting the first circuit pattern and the second circuit pattern, wherein the vias are filled with conductive material; and a plurality of LED chips disposed on the carrier portion of the substrate and electrically connected with the electrical connection portion. The vias filled with the conductive material are utilized to enhance heat dissipation of the substrate.

### BACKGROUND OF THE INVENTION

1. Field of the Invention

The present invention relates to a chip package structure, and more particularly to an LED chip package structure.

2. Description of the Prior Art

Recently, LEDs (light-emitting diodes) have gained popularity in illumination applications, and the power of LEDs has become increasingly higher thereby causing the heat generated to rise. If heat is not removed in time, the operation temperature of the LED would increase, which may impact its normal operation, and may even damage the LED.

In general, an LED package structure includes a substrate, an insulation layer, an LED chip and a plurality of gold wires. The substrate is usually a lead frame, metal substrate, ceramic substrate, Metal Core Printed Circuit Board (MCPCB) or the like. The LED package structure is ordered into the following bottom up sequence: the substrate, insulation layer and LED chip. The substrate and the LED chip are connected by the gold wires. When illuminating, the LED chip dissipates heat through the substrate.

However, since the heat of the LED is only dissipated through the aforementioned types of substrate, the heat dissipation effect may be poor. Besides, if an extra heat sink or another heat dissipation device is used, the cost may be substantially increased. Therefore, it is highly desirable a solution in improving the heat dissipation for the LED package structure is provided.

### SUMMARY OF THE INVENTION

The present invention is directed to providing an LED chip package structure utilizing vias filled with conductive material to conduct the circuit on the upper and lower layers of the substrate to enhance heat dissipation of the substrate.

According to an embodiment, the chip package structure includes a substrate; a first circuit pattern disposed on a surface of the substrate, wherein the first circuit pattern is divided into an electrical connection portion and a carrier portion; a second circuit pattern disposed on another surface of the substrate; a plurality of vias disposed in the substrate and connecting the first circuit pattern and the second circuit pattern, wherein the vias are filled with conductive material; and a plurality of LED chips disposed on the carrier portion of the substrate and electrically connected with the electrical connection portion.

The objective, technologies, features and advantages of the present invention will become more apparent from the following description in conjunction with the accompanying drawings, wherein certain embodiments of the present invention are set forth by way of illustration and examples.

### BRIEF DESCRIPTION OF THE DRAWINGS

FIG. 1, FIG. 2 and FIG. 3 are schematic sectional diagrams illustrating the LED chip package structures according to an embodiment of the present invention.

### DESCRIPTION OF THE PREFERRED EMBODIMENT

Detailed description of the present invention is provided below. The embodiments are described by merely way of example, and should not be used to limit the scope of the claims.

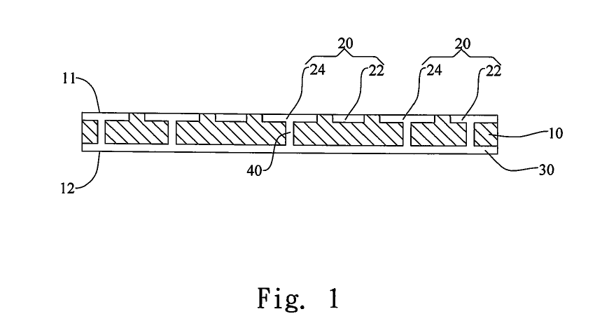

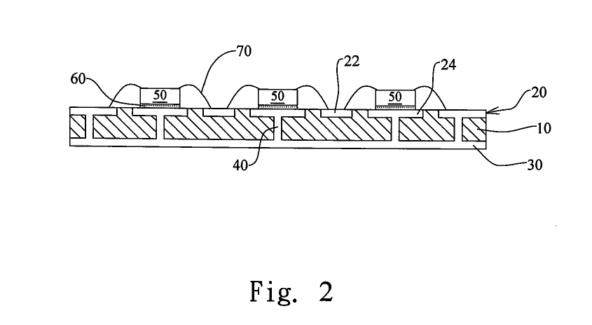

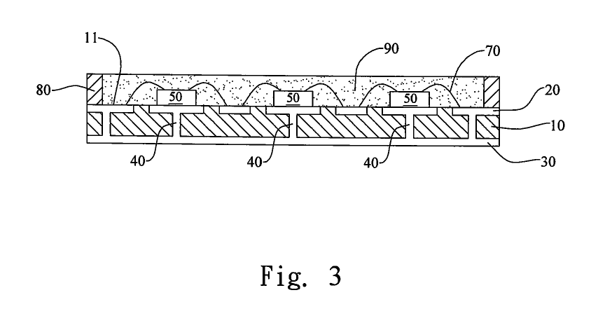

Referring to FIG. 1 and FIG. 2, there are illustrated schematic sectional diagrams of the LED chip package structures according to an embodiment. As illustrated in FIG. 1 and FIG. 2, the LED chip package structure includes a substrate 10, a first circuit pattern 20, a second circuit pattern 30, a plurality of vias 40 and a plurality of LED chips 50. The substrate 10 has a surface 11 and another surface 12 opposite to the surface 11. The first circuit pattern 20 is disposed on the surface 11 of the substrate 10, wherein the first circuit pattern 20 includes an electrical connection portion 22 and a carrier portion 24. The second circuit pattern 30 is disposed on the other surface 12 of the substrate 10. The vias 40 are disposed in the substrate 10 and connecting the first circuit pattern 20 with the second circuit pattern 30, wherein the vias 40 are filled with a conductive material including but not limited to Cu. Through the conductive material of the vias, the heat of the first circuit pattern 20 may be transferred to the second circuit pattern 30. Also, the vias 40 can electrically connect the first circuit pattern 20 with the second circuit pattern 30. As illustrated in FIG. 2, the LED chips 50 are disposed on the carrier portion 24 of the substrate 10 and are electrically connected with the electrical connection portion 22.

Continuing the above description, according to an embodiment in reference to FIG. 2, the vias 40 connect the carrier portion 24 with the second circuit pattern 30 to enhance heat dissipation for the LED chips 50. Moreover, the vias 40 also connect the electrical connection portion 22 and the second circuit pattern 30 to conduct electrically. As illustrated in FIG. 2, the LED chip package structure of this embodiment further includes an adhesive layer 60 disposed between the LED chips 50 and the carrier portion 24, wherein the adhesive layer 60 is made of insulating material, and is for fixing the LED chips 50 and insulating the LED chips 50 from the carrier portion 24. According to an embodiment, as illustrated in FIG. 2, a plurality of wires 70 are disposed between the LED chips 50 and the electrical connection portion 22 for electrically connecting the LED chips 50 and the electrical connection portion 22.

Referring to FIG. 3, according to an embodiment, the LED chip package structure further includes a retaining wall 80 disposed on the surface 11 of the substrate 10 and surrounds the LED chips 50. According to an embodiment, the retaining wall 80 is made of insulating material. As illustrated in the figure, an encapsulating body 90 is formed within the retaining wall 80 and encapsulates the LED chips 50, the wires 70 and the first circuit pattern 20. The material of the encapsulating body 90 includes fluorescent power and silica gel. Furthermore, a reflective layer (not illustrated) can be formed on an inner surface of the retaining wall 80, or between the inner surface of the retaining wall 80 and the encapsulating body 90 to increase the reflected light source.

In the foregoing embodiments, the first circuit pattern 20, second circuit pattern 30 on the substrate 10 and the vias 40 filled with the conductive material in the substrate 10 can be formed during the substrate 10 is manufactured so that only die attaching, wire bonding and plastic molding are required subsequently to complete the LED chip package structure with efficient heat dissipation. In addition, such efficient heat dissipation structure does not incur too much extra cost.

To summarize the foregoing description, the LED chip package structure according to the present invention utilizes vias filled with the conductive material to conduct the upper and lower circuits of the substrate to enhance heat dissipation of the substrate.

While the invention is susceptible to various modifications and alternative forms, a specific example thereof has been shown in the drawings and is herein described in detail. It should be understood, however, that the invention is not to be limited to the particular form disclosed, but to the contrary, the invention is to cover all modifications, equivalents, and alternatives falling within the spirit and scope of the appended claims.

What is claimed is:

1. An LED package structure comprising:
a substrate;
a first circuit pattern disposed on a surface of the substrate, wherein the first circuit pattern is divided into an electrical connection portion and a carrier portion;
a second circuit pattern disposed on another surface of the substrate;
a plurality of vias disposed in the substrate and connecting the first circuit pattern and the second circuit pattern, wherein the vias are filled with conductive material; and
a plurality of LED chips disposed on the carrier portion of the substrate and electrically connected with the electrical connection portion.

2. The LED package structure according to claim 1, further comprising a retaining wall disposed on the surface of the substrate and surrounding the plurality of LED chips.

3. The LED package structure according to claim 2, further comprising an encapsulating body formed within the retaining wall and encapsulating the LED chip and the first circuit pattern.

4. The LED package structure according to claim 3, wherein material of the encapsulating body comprises fluorescent powder and silica gel.

5. The LED package structure according to claim 1, wherein the vias connect the carrier portion with the second circuit pattern.

6. The LED package structure according to claim 1, wherein the vias connect the electrical connection portion with the second circuit pattern.

7. The LED package structure according to claim 1, further comprising an adhesive layer disposed between the LED chips and the carrier portion.

8. The LED package structure according to claim 1, further comprising a plurality of wires for electrically connecting the LED chips and the electrical connection portion.
